(19) United States
(12) Patent Application Publication
(10) Pub. No.: US 2010/0212939 A1
(43) Pub. Date: Aug. 26, 2010

(54) MODULE, CIRCUIT BOARD, AND MODULE MANUFACTURING METHOD

(75) Inventors: Shoji Ito, Sakura-shi (JP); Yusuke Nakatani, Sakura-shi (JP); Ryo Takami, Sakura-shi (JP); Tadanori Ohminato, Sakura-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIKURA LTD., Kohtoh-ku, Tokyo (JP)

(21) Appl. No.: 12/681,283

(22) PCT Filed: Oct. 3, 2008
(86) PCT No.: PCT/JP2008/068062

§ 371 Date: Apr. 1, 2010

(30) Foreign Application Priority Data
Oct. 3, 2007 (JP) 2007-259467

(51) Int. Cl. H05K 1/03; H05K 1/16; H01R 43/00

(52) U.S. Cl. 174/255; 174/260; 29/854

(57) ABSTRACT

A module of the present invention is provided with; a circuit board in which conductors are patterned on an insulating layer, and a functional element that is mounted on the conductor pattern face down via bumps. An aperture section is formed in an area of the circuit board which is the functional element mounting position, which is smaller than, a projected surface of the functional element, and is inside of a region where the bumps are joined with the conductors. A gap between the functional element and the circuit board, and the aperture section are sealed by a sealing resin.

### TECHNICAL FIELD

The present invention relates to a module, a circuit board, and a method of manufacturing the module. In particular, it relates to a module in which functional elements are mounted face down on a circuit board, and the gaps between the functional elements and the circuit board are sealed with a sealing resin.

Priority is claimed on Japanese Patent Application No. 2007-259467, filed Oct. 3, 2007, the content of which is incorporated herein by reference.

### BACKGROUND ART

In recent years, it is increasingly required for electronic equipment systems to be made lighter, thinner, shorter and smaller, more miniaturized, have lower power consumption, more functions, and high-reliability. Furthermore, accompanying high degrees of integration, functional elements such as semiconductor elements with very high pin counts and fine pitches, and the like, have been appearing according to Rent's rule.

On the other hand, in processes for mounting such functional elements, problems have been confronted regarding how these functional elements with very high speed, very high heat generation, multiple terminals, and fine pitches can be mounted at high density while maintaining reliability, so the mounting forms have become complicated and diverse.

Especially, as the high level of functionality of electronic equipment develops, the parts used are required to deal with the high levels of functionality. Circuit boards such as printed circuit boards and functional elements such as semiconductor elements mounted thereon are no exception.

For this requirement, high circuit density technology is required for circuit boards. Making circuits with a fine pitch can be given as a typical method. In particular, for an LCD (Liquid Crystal Display) COF (Chip on Film) substrate, circuits with a fine pitch of 35 μm have already come into practical use.

Moreover, as mentioned above, high pin count can be given as an example of a technology required for semiconductor elements. Accompanying such high pin counts, the pitch of the electrodes is also required to be a fine pitch.

As a technique for mounting a semiconductor element on a printed circuit board, there is a method of wire bonding in which the semiconductor element is loaded on the printed circuit board face up, and the electrodes of the two are connected by metal wires. However, there is a problem regarding the connections between the fine pitch electrodes, in that the wires make contact with each other due to the wires getting tangled, which causes short circuits. Furthermore, since the printed circuit board and the semiconductor element are electrically connected by wires on the outside of the outer periphery of the semiconductor element, a predetermined spacing is necessary for the connections, so that it is not suitable for mounting at high density.

As another technique for mounting a semiconductor element on a printed circuit board, there is a method of TAB (Tape Automated Bonding) (also called a film carrier method). This method is suitable for automation, so it is suitable for mass production, but there is a problem in the supply system of TAB chips. Therefore, only limited chips can be obtained.

Consequently, as a method for solving the above-described problems, flip chip bonding has come into practical use in which semiconductor elements are connected with a printed circuit board face down. In this method, since the circuit of the printed circuit board and the electrodes of the semiconductor element are connected directly and electrically, it is difficult for short circuits to be caused, and it is easy to deal with fine pitch counts compared with wire bonding. Furthermore, since the connections are on the inside of the periphery of the semiconductor element, it is possible to save space when mounting on the printed circuit board. Therefore, the technique is suitable for mounting at high density. Especially, the connections between a printed circuit board and a semiconductor element with COF and TAB mainly use this method.

As examples of methods of flip chip bonding, there can be mentioned; a method for connecting using an ACF (Anisotropic Conductive Film), a method for connecting the electrodes of a semiconductor element and a printed circuit board using solder, a method for connecting the electrodes of a semiconductor element and a printed circuit board using conductive paste, a method for joining the gold bumps of a semiconductor element and a tin plated layer on a printed circuit board using thermo compression bonding, a method for joining the gold bumps of a semiconductor element and a gold-plated layer on a printed circuit board using thereto-compression bonding or ultrasonic wave application, and the like.

Using ACF, it is possible to perform electrical connection and resin sealing between a semiconductor element and a printed circuit board at the same time. However, in the case of the other methods described above, it is necessary to fill the gap between the semiconductor element and the printed circuit board with sealing resin after joining the electrodes. FIG. 1 is a diagram schematically showing a method of resin sealing after the flip chip bonding, and FIG. 2 is a cross-sectional diagram showing a module 100 obtained by this method. The method of resin sealing is a method in which, as shown in FIG. 1, a sealing resin 107 is applied on a first face 105a of a semiconductor element 105, the sealing resin 107 fills underneath the semiconductor element 105 using a capillary phenomenon generated in the gaps in the circuit of the printed circuit board 103, and as shown in FIG. 2, the sealing resin 107 fills in between the printed circuit board 103 and the semiconductor element 105, and the surroundings of bumps 104 (refer to non-patent document 1).

[Non-Patent Document 1] Problems of Materials and Methods in High Density COIF Packaging, and Countermeasures Thereof, Collaboration by Shiro Ozaki, et al. Technical Information Institute, 2003, Chapter 3 Item 1 p. 143 to p. 149

### DISCLOSURE OF INVENTION

### Problems to be Solved by the Invention

However, when the gap between the semiconductor element 105 and the printed circuit board 103 is sealed with the sealing resin 107 using the above-described method, babbles sometimes contaminate the sealing resin 107. In the case where bubbles are located between an electrode of the semiconductor element 105 and an electrode of the printed circuit board 103, conductive resistance increases due to the bubbles, so there is concern about continuity failures occurring. Moreover, cracks are generated due to the bubbles, so there is concern about detachment between the electrodes. Furthermore, detaching progresses gradually from the bubbles due to the differences in the coefficients of thermal expansion between the semiconductor element 105, the printed circuit board 103, and the sealing resin 107, so there is concern about detachment of the electrodes.

In order to fill the sealing resin 107 without contamination by bubbles, it is preferable that the projected area of the semiconductor element 105 on the printed circuit board 103 is as small as possible. The reasons are that the smaller the semiconductor element 105, the smaller the sealing area may be, which enables the probability of contamination by bubbles to be reduced, and that when applying the sealing resin 107 to the side of the semiconductor element 105 when filling, the distance from the place applied to the place it needs to fill may be small.

However, especially in a semiconductor element for which a high level of functionality is required, since the number of electrodes needs to be high, it is difficult to miniaturize the semiconductor element, so it is necessary to overcome the above-described problems.

The present invention has been made in view of the above-described background art, and therefore has objects of providing; a module in which the probability of contamination by bubbles is reduced regardless of the size of the semiconductor element, a method of manufacturing the module, and a circuit board incorporated in the module.

### Means for Solving the Problem

The present invention adopts the followings to solve the above problems in order to achieve the objects.

(1) A module according to the present invention is a module provided with; a circuit board in which conductors are patterned on a first face of an insulating layer, and a functional element that is mounted on the conductors face down via bumps, wherein the module includes: an aperture section, which is formed in a thickness direction of the insulating layer in an area at a location of the circuit board where the functional element is mounted, which is smaller than a projected surface of the functional element and is inside of a region where the bumps are joined with the conductors; and a sealing resin that seals a gap between the functional element and the circuit board, and the aperture section.

According to the module described in (1), the aperture section is formed in an area at the location of the insulating layer where the functional element is mounted that is smaller than the projected surface of the functional element and is inside of the region where the bumps are joined with the conductors. Therefore, the area of overlap between the circuit board and the functional element is small, and hence it is possible to reduce the probability of bubbles contaminating the sealing resin between the circuit board and the functional element. Consequently, it is possible to provide a module in which an increase in conductive resistance due to bubbles, and detaching of the circuit board and the functional element, are not likely to occur. Moreover, it is possible to confirm whether or not there is contamination by bubbles from the aperture section visually and easily. Therefore, it is possible to confirm easily whether or not there are bubbles in the sealing resin of a module during storage, before or after transport, or in a module in use.

(2) Preferably the sealing resin protrudes from the aperture section to a second face of the insulating layer, and has a region that spreads to an area wider than the aperture section.

In the case of (2), if an external impact is applied to the module, the impact is relieved by the region. Therefore, the resistance to external impact is improved.

(3) A circuit board according to the present invention is a circuit board in which conductors are patterned on a first face of an insulating layer, and a functional element is mounted face down on the conductors, wherein an aperture section is formed in a thickness direction of the insulating layer in an area that is smaller than a projected surface of the functional element and is inside of a region where the functional element is electrically joined with the conductors.

According to the circuit board described in (3), when mounting the functional element and sealing it, even if bubbles contaminate the sealing resin, the bubbles can be eliminated via the aperture section. As a result, using the circuit board of the present invention, it is possible to easily obtain a module in which it is difficult for bubbles to exist in the sealing resin. Moreover, since sealing by the sealing resin can be performed while confirming, from the aperture section, whether or not there are bubbles, it is possible to improve the work efficiency and improve the yield.

(4) A manufacturing method of a module according to the present invention is a method of manufacturing a module provided with; a circuit board in which conductors are patterned on a first face of an insulating layer, and a functional element that is mounted on the conductors face down via bumps, and in which an aperture section is formed in a thickness direction of the insulating layer, in an area at a location of the circuit board where the functional element is mounted that is smaller than a projected surface of the functional element and is inside of a region where the bumps are joined with the conductors, and a gap between the functional element and the circuit board, and the aperture section, are sealed using a sealing resin. The method includes: mounting the functional element on the conductors of the circuit board via the bumps; and sealing the gap between the functional element and the circuit board, and the aperture section, using the sealing resin.

According to the manufacturing method of a module described in (4), since an aperture section is formed, the area of overlap between the functional element and the circuit board is small, and hence it is possible to reduce the probability of contamination by bubbles. Even if bubbles contaminate the sealing resin, the bubbles can be eliminated via the aperture section. Accordingly, it is possible to improve the yield, and obtain a module in which it is difficult for bubbles to exist in the sealing resin. Furthermore, since sealing by the sealing resin can be performed while confirming, from the aperture section, whether or not there are bubbles, it is possible to improve the work efficiency.

(5) In the resin sealing, preferably the sealing resin is injected such that it protrudes from the aperture section to a second face of the insulating layer, and forms a region that spreads to an area wider than the aperture section on the second face of the insulating layer.

In the case of (5), by forming this region, it is possible to form a module in which the resistance to external impact is improved.

(6) In the resin sealing, preferably the sealing resin is injected from at least one pair of opposing sides of the functional element.

In the case of (6), there is concern about bubbles being included at the location where the sealing resin injected from both sides meets under the functional element. However, the bubbles can be eliminated via the aperture section.

(7) In the resin sealing, preferably the sealing resin is injected from the aperture section.

In the case of (7), since the sealing resin flows from the aperture section towards the four sides of the functional element, even in the case where there is contamination by bubbles, it is possible to eliminate the bubbles from the four sides of the semiconductor element. Moreover, since the sealing resin can be disposed in the aperture section, it is easy to locate the sealing resin at an appropriate position when it is disposed.

(8) In the resin sealing, preferably the sealing resin is injected with a second face side of the insulating layer being at a lower pressure than the first face side of the insulating layer.

In the case of (8), the sealing resin flows from at least one pair of opposing sides of the functional element to the aperture section, so that it is possible to help the sealing resin to fill the gap between the functional element and the circuit board, and the aperture section. As a result, it is possible to shorten the manufacturing time.

(9) In the resin sealing, preferably the sealing resin is injected with the first face side of the insulating layer being at a lower pressure than a second face side of the insulating layer.

In the case of (9), the sealing resin flows from the aperture section to the four sides of the functional element, so that it is possible to help the sealing resin fill the gap between the functional element and the circuit board, and the aperture section. Therefore it is possible to shorten the manufacturing time.

(10) Preferably the resin sealing comprises: mounting the circuit board on a suction stage on which a plurality of suction holes is provided such that the second face of the circuit board is on the suction stage side; fixing the circuit board on the suction stage by suctioning from the suction holes; and applying the sealing resin to at least one pair of opposing sides of the functional element in a state in which it is sucked down, and filling the gap between the functional element and the circuit board, and the aperture section, with the sealing resin.

In the case of (10), by means of suction, it is possible to easily make the pressure on the second face side of the insulating layer lower than the first face side of the insulating layer. Furthermore, it is possible to eliminate bubbles effectively.

(11) Preferably a recess is provided in a location of the suction stage, facing the aperture section.

In the case of (11), when filling the sealing resin, it is possible to prevent the sealing resin from becoming attached to the stage.

(12) Preferably the resin sealing comprises: mounting the circuit board on a suction stage on which a plurality of suction holes is provided such that the functional element is on the suction stage side; fixing the circuit board on the suction stage by suctioning from the suction holes; and applying the sealing resin from the aperture section in a state in which it is sucked down, and filling the gap between the functional element and the circuit board, and the aperture section, with the sealing resin.

In the case of (12), by suction it is possible to easily make the pressure on the first face side of the insulating layer lower than the second face side of the insulating layer. Furthermore, it is possible to eliminate bubbles effectively.

(13) Preferably a recess is provided in a location of the suction stage, facing the functional element.

In the case of (13), the functional element can be accommodated in the recess, so that it is possible to increase the adhesion between the circuit board and the stage.

### EFFECTS OF THE INVENTION

According to the present invention, regardless of the size of the functional element that is used, it is possible to obtain a module and the like in which the probability of contamination by bubbles is reduced.

### BRIEF DESCRIPTION OF THE DRAWINGS

FIG. 1 is a diagram showing a typical resin sealing method after conventional flip chip bonding.

FIG. 2 is a cross-sectional diagram schematically showing a conventional module obtained by mounting a semiconductor element on a printed circuit board.

FIG. 3 is a cross-sectional diagram schematically showing a module according to a first embodiment of the present invention.

FIG. 4 is a cross-sectional diagram schematically showing a module according to a second embodiment of the present invention.

FIG. 5 is a cross-sectional diagram schematically showing a circuit board according to the first embodiment of the present invention.

FIG. 6A is a diagram showing a step in a manufacturing method (first manufacturing method) of a module of the present invention.

FIG. 6B is a diagram showing a step in a manufacturing method (first manufacturing method) of a module of the present invention.

FIG. 6C is a diagram showing a step in a manufacturing method (first manufacturing method) of a module of the present invention.

FIG. 7A is a diagram showing a step in a manufacturing method (first manufacturing method) of a module of the present invention.

FIG. 7B is a diagram showing a step in a manufacturing method (first manufacturing method) of a module of the present invention.

FIG. 8A is a diagram showing a step in a manufacturing method (first manufacturing method) of a module of the present invention.

FIG. 8B is a diagram showing a step in a manufacturing method (first manufacturing method) of a module of the present invention.

FIG. 8C is a diagram showing a step in a manufacturing method (first manufacturing method) of a module of the present invention.

FIG. 9 is a diagram showing a step in a manufacturing method (first manufacturing method) of a module of the present invention.

FIG. 10A is a diagram showing a step in a manufacturing method (second manufacturing method) of a module of the present invention.

FIG. 10B is a diagram showing a step in a manufacturing method (second manufacturing method) of a module of the present invention.

FIG. 10C is a diagram showing a step in a manufacturing method (second manufacturing method) of a module of the present invention.

FIG. 10D is a diagram showing a step in a manufacturing method (second manufacturing method) of a module of the present invention.

FIG. 11A is a diagram showing a manufacturing method of a comparative example 1.

FIG. 11B is a diagram showing a manufacturing method of the comparative example 1.

FIG. 11C is a diagram showing a manufacturing method of the comparative example 1.

FIG. 12A is a diagram showing a manufacturing method of a comparative example 2.

FIG. 12B is a diagram showing a manufacturing method of the comparative example 2.

FIG. 12C is a diagram showing a manufacturing method of the comparative example 2.

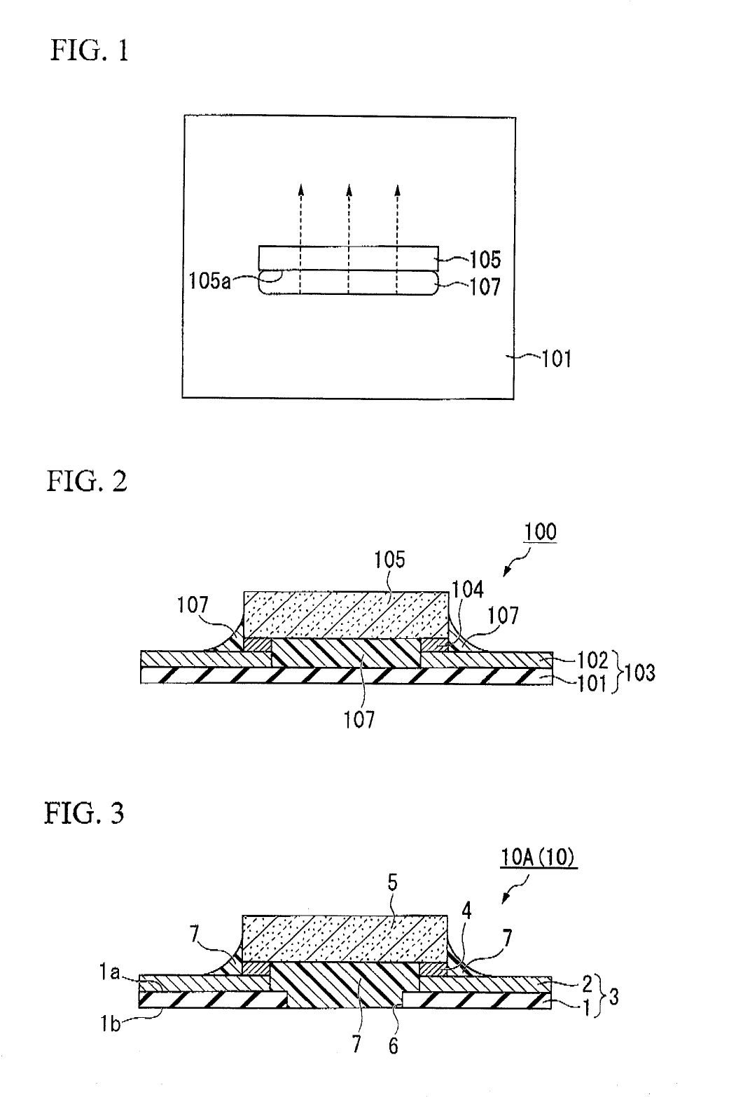

### BRIEF DESCRIPTION OF THE REFERENCE SYMBOLS

1 Insulating Layer
2 Conductor
3 Circuit Board
4 Bump
5 Functional Element
6 Aperture Section
7 Sealing Resin
8 Solder Resist
10 (10A, 10B) Module
21 Stage
22 Suction Hole

### BEST MODE FOR CARRYING OUT THE INVENTION

Hereunder is a detailed description of embodiments of the present invention with reference to the drawings.

### Module

### First Embodiment

FIG. 3 is a cross-sectional diagram schematically showing a module 10A (10) according to a first embodiment of the present invention. The module 10 comprises, schematically, a circuit board 3 in which conductors 2 axe patterned on a first face 1a of an insulating layer 1, and a functional element 5 that is mounted on the conductors 2 face down via bumps 4. An aperture section 6 is formed in an area at a location of the circuit board 3 where the functional element 5 is mounted that is smaller than the projected surface of the functional element 5 and is inside of a region where electrodes 4 are joined with the conductors 2. Furthermore, a gap between the functional element 5 and the circuit board 3, and the aperture section 6, are sealed with a sealing resin 7.

The insulating layer 1 is made from a resin such as polyimide, SiO₂, BCB, Al₂O₃, crystallized glass or the like, for example. It is preferable to use glass epoxy from the advantage that it increases the reliability of the electrical characteristics and mechanical characteristics. It is preferable to use paper phenolic single sided circuit board from the advantage of low cost. Moreover, it is preferable to use BT resin for high thermostability. It is especially preferable to use PPE or polyimide for high-speed packaging.

For the conductors 2, a variety of materials can be used, for example Cu, Al, Au, Ni or a compound metal of these.

For the circuit board 3, a variety of types of circuit board can be used. As examples, there can be given; a printed circuit board, an organic circuit board, a rigid circuit board, a paper-based copper-clad laminate, a fiberglass copper-clad laminate, a heat resistant thermoplastic circuit board, a composite copper-clad laminate, a flexible board, a polyester copper-clad film, a glass fabric epoxy copper-clad laminate, a polyimide copper-clad film, an inorganic circuit board, a ceramic circuit board, an alumina system circuit board, a high thermal conductivity circuit board, a low-permittivity circuit board, a low temperature sintered circuit board, a metal circuit board, a metal base circuit board, a metal core circuit board, a hollow circuit board, a composite circuit board, a built-in resistor and capacitor circuit board, a resin/ceramic circuit board, a resin/silicon circuit board, a glass substrate, a silicon substrate, a diamond substrate, a paper phenolic substrate, a paper epoxy substrate, a glass composite substrate, a glass epoxy substrate, a Teflon (registered trademark) substrate, an alumina substrate, a composite substrate, a composite substrate of an organic material and an inorganic material, and the like. Furthermore, the structure may be a single-sided board, a double-sided board, a two-layer board, a multilayer board, or a build-up board.

For the functional element 5, a variety of functional elements can be used. As examples, there can be given; electronic parts such as semiconductor elements, integrated circuits, resistors and capacitors, electronic functional elements, optical functional elements, quantized functional elements, electronic devices and optical devices which use tunnel effects, optical memory effects, or the like, switches that use the biomolecular structure or quantum effects of a molecular aggregate or an artificial superlattice, circuit elements such as memory, amplifiers, and transformers, material detecting elements, and the like. Moreover, the structure may be a bare chip, a single chip package, a multi-chip package, or the like.

For the bumps 4, which electrically connect the functional element 5 and the conductors 2, a variety of materials can be used. Gold bumps, solder bumps and the like can be given as examples, and they may include pillars made from Ag, Ni, Cu or the like. Furthermore, the material may be hard solder or soft solder. As examples, there can be given; Mg solder, Al solder, Cu—P solder, Au solder, Cu—Cu—Zn solder, Pd solder, Ni solder, Ag—Mn solder, Sn—Pb, Sn—Zn, Sn—Ag, Sn—Sb, Cd—Zn, Pb—Ag, Cd—Ag, Zn—Al, Sn—Bi, and the like.

Plating using tin or gold may be applied on the surface of the conductors 2. In this case, the plating and the bumps 4 arranged on the electrode of the functional element 5 are joined. The plating to be used is selected appropriately depending on the wettability with the bumps.

For the sealing resin 7, a variety of materials can be used. Cresol, epoxy resin such as the novolak system, the bisphenol A type system and the alicyclic type system, and the like can be given as examples. In the sealing resin 7, furthermore, a hardening agent, a catalyst (accelerating agent), a coupling agent, a parting agent, a fire-resistant auxiliary agent, a coloring agent, a low stress additive agent, an adhesion characteristic enhancing agent, a plastic characteristic enhancing agent, or a filler (filling agent) such as silica may be incorporated.

In the module 10 of the present invention, the aperture section 6 is formed in an area at a location of the insulating layer 1 where the functional element 5 is mounted that is smaller than the projected surface of the functional element 5 and is inside of the region where the electrodes are joined with the conductors 2. Therefore, the area of overlap between the circuit board 3 and the functional element 5 is small, and hence it is possible to reduce the probability of bubbles contaminating the sealing resin 7. As a result, it is possible to provide a module 10 in which an increase in conductive resistance due to bubbles, and detaching of the functional element 5 from the circuit board 3, are not likely to occur. Moreover, it is possible to confirm whether or not there is contamination by bubbles from the aperture section 6 visually and easily. Therefore, it is possible to confirm easily whether or not there are bubbles in the sealing resin 7 of a module 10 during storage, before or after transport, or in a module 10 in use. Even if bubbles contaminate the sealing resin 7, and the bubbles expand, causing the sealing resin 7 to swell, it is possible to relieve the stress due to the expansion via the aperture section 6.

The present invention can be applied even if the construction is such that an adhesive layer is formed on the first face 1a of the insulating layer 1 (for example, an insulating material film (base film) or the like), and conductors 2 are formed on the adhesive layer, and the circuit board 3 is covered and protected by the insulating material excluding the area where the bumps 4 are joined.

Moreover, in the case where the conductors 2 extend considerably toward the inside under the functional element 5, it is desirable that an aperture section is formed that also passes through the conductors 2. On the other hand, in the case where they stop outside under the functional element 5, the aperture does not need to pass through the conductors 2.

### Second Embodiment

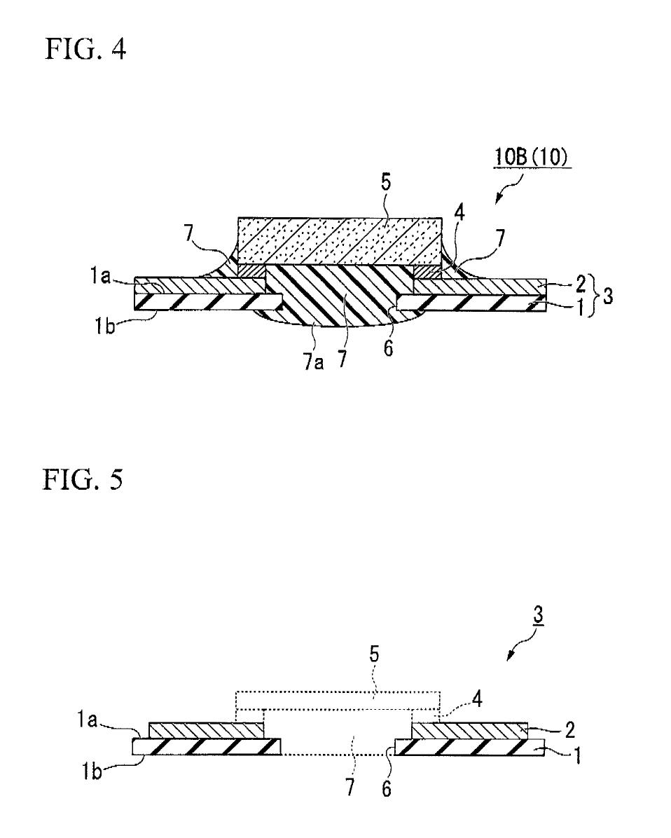

FIG. 4 is a cross-sectional diagram schematically showing a module 10B (10) according to a second embodiment of the present invention. The points of difference between the module 10B of the present embodiment and the module 10A of the first embodiment are that the sealing resin 7 forms a region 7a that protrudes toward the second face 1b of the insulating layer 1 from the aperture section 6, and that extends to an area wider than the aperture section 6.

In this manner, since the sealing resin 7 has the region 7a, when an external impact is applied to the module 10B, the impact is relieved by the region 7a. Therefore, the resistance against external impact improves. Consequently, if the module 10B of the present embodiment is used, it is possible to provide electronic equipment in which it is difficult for damage due to external impact to occur.

FIG. 5 is a cross-sectional diagram schematically showing a circuit board 3 of the present invention. The circuit board 3 of the present invention has conductors 2 patterned on the first face 1a of the insulating layer 1, on which the functional element 5 is mounted face down. Furthermore, the aperture section 6 is arranged in the thickness direction of the insulating layer 1 in an area that is smaller than the projected surface of the functional element 5 and is inside the region where the functional element 5 is joined with the conductors 2.

The insulating layer 1, the conductors 2, and the aperture section 6 are the same as in the module 10 described above.

According to the circuit board 3 of the present invention, the aperture section 6 is formed in the insulating layer 1 in an area at the location where the functional element 5 is mounted that is smaller than the projected surface of the functional element 5 and is inside of the region where the bumps 4 are joined with the conductors. Therefore, when the functional element 5 is mounted on the circuit board 3 of the present invention, and the gap between the functional element 5 and the circuit board 3, and the aperture section 6, are sealed using the sealing resin 7, even if bubbles contaminate the sealing resin 7, the bubbles can be eliminated via the aperture section 6. Accordingly, using the circuit board 3 of the present invention, it is possible to easily obtain a module in which it is difficult for bubbles to exist in the sealing resin 7 between the functional element 5 and the circuit board 3. Furthermore, since sealing by the sealing resin 7 can be performed while confirming, from the aperture section 6, whether or not there are bubbles, it is possible to improve the yield.

### [Manufacturing Method of Module]

Process flow in a method of manufacturing a module of the present invention will be described.

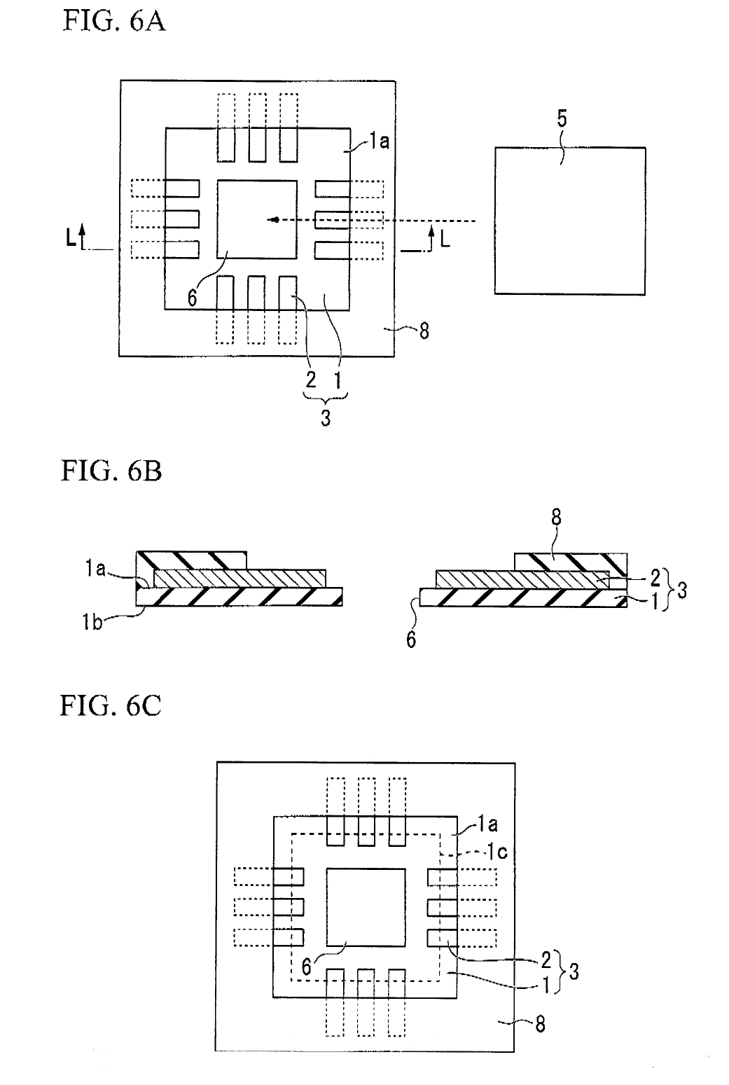

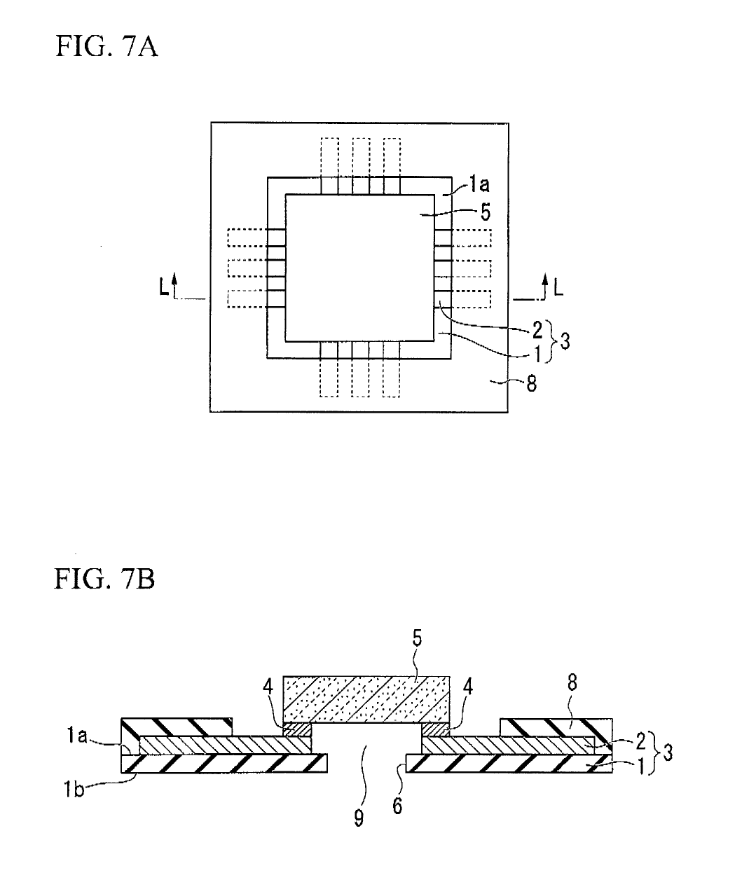

FIGS. 6A, 6B and 6C, FIGS. 7A and 7B, FIGS. 8A, 8B and 8C, and FIG. 9 are process diagrams schematically showing a method of manufacturing a module of the present invention (first manufacturing method). FIG. 6A and FIG. 7A are top views, and FIG. 6B and FIG. 7B are cross-sectional diagrams through L-L of FIGS. 6A and 7A respectively.

Firstly, as shown in FIG. 6A, a circuit board 3 in which conductors 2 are patterned on the first face 1a of an insulating layer 1, and a functional element 5, are prepared.

The circuit board 3 can be obtained by forming the conductors 2 on the first face 1a of the insulating layer 1 using a conventionally known method such as plating, a printing process, a photolithographic method, or the like. Metal plating is performed on the surface of the conductors 2 as required. The conductors 2 may be protected by a solder resist 8 excluding the area on the circuit board 3 where the functional element 5 is mounted. In the present embodiment, a case is described in which the solder resist 8 is applied. An aperture section 6 is formed in an area at the location of the circuit board 3 (insulating layer 1) where the functional element 5 is mounted that is smaller than the projected surface of the functional element 5 and is inside of the region where the bumps are joined with the conductors 2. FIG. 6C shows as a broken line, the location of the projected surface 5a of the functional element 5 in the case where the functional element 5 is projected on the circuit board 3.

In addition, bumps are formed on the electrodes of the functional element 5.

As shown in FIG. 6B, the cross-sectional structure of the circuit board 3 is a multi-layer structure of the insulating layer 1, the conductors 2, and the solder resist 8 in that order from the bottom.

Next, as shown in FIG. 7A and FIG. 7B, the functional element 5 is mounted on the circuit board 3 such that the functional element 5 and the circuit board 3 (conductors 2) are connected electrically via the bumps 4.

The electrical connection of the bumps 4 of the functional element 5 and the conductors 2 can be made, in the case where gold bumps 4 are used as the bumps 4 and the surface of the conductors 2 is tinned, for example, by the gold and tin being joined eutectically. For the joining method, the surface of the conductors 2 is gold-plated, and the gold bumps 4 and the gold-plating of the conductors 2 are bonded by thermo-compression, or they may be joined by applying ultrasonic waves. Moreover, they may also be joined by gold solder, or joining by the C4 technique (Controlled Collapse Chip Connection).

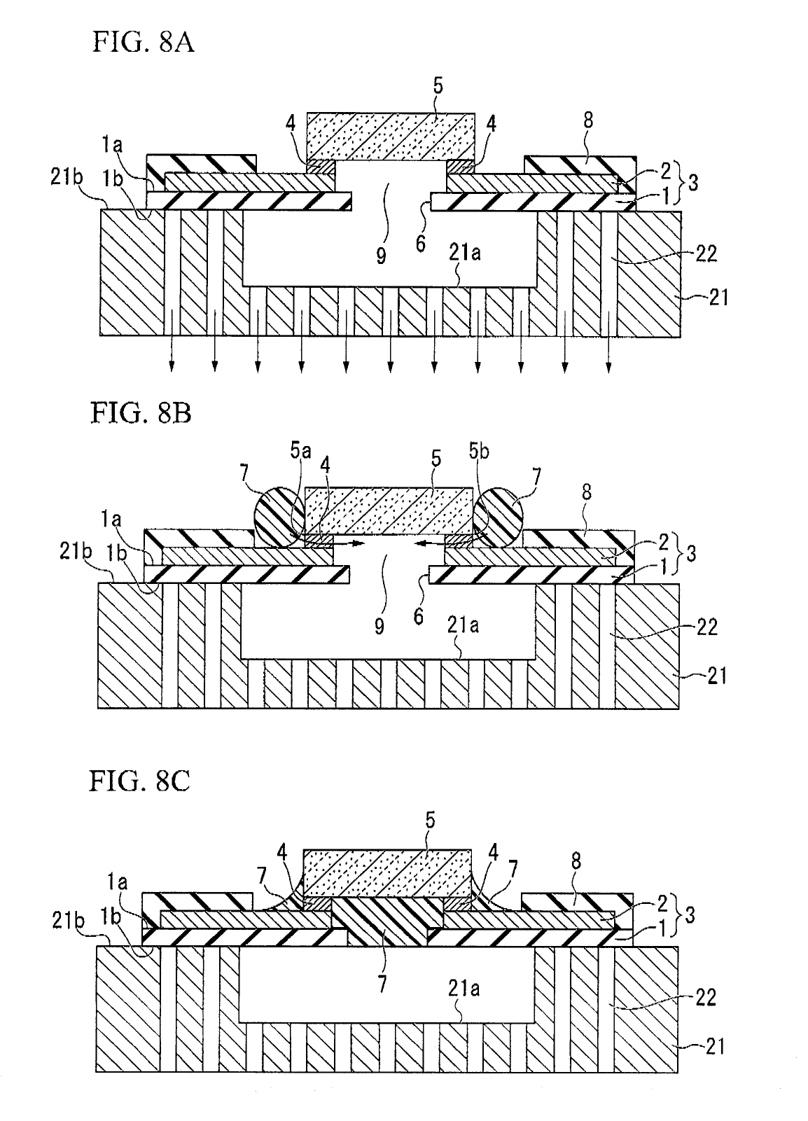

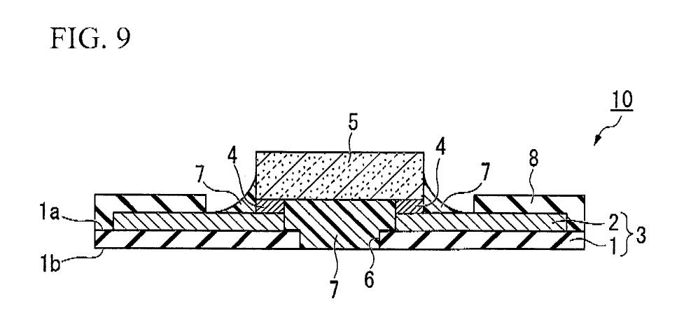

Next, as shown in FIG. 8A, the circuit board 3 on which the functional element 5 is mounted, is placed on a stage 21 in which a plurality of holes 22 for suction (suction holes) is provided. The stage 21 has a recess 21a in which the region surrounding the aperture section 6 of the circuit board is concave. The recess 21a prevents sealing resin from adhering to the stage 21 when the sealing resin is applied later.

When placing the circuit board 3 on which the functional element 5 has been mounted on the stage 21, the arrangement is such that the second face 1b of the insulating layer 1 and a face 21b in which the recess 21a of the stage 21 is formed make contact.

Afterwards, by suctioning atmospheric gas from the suction holes 22 in the direction indicated by the arrows in FIG. 8A, the circuit board 3 on which the functional element 5 is mounted is fixed on the stage 21. By suctioning in this manner, the second face 1b side of the insulating layer 1 and the recess 21a of the stage 21 are at a lower pressure than the first face 1a of the insulating layer on which the functional element 5 is mounted, so the atmospheric gas flows from the functional element 5 side toward the recess 21a of the stage 21.

Next, as shown in FIG. 8B, the sealing resin 7 is applied to both sides 5a and 5b of the functional element 5, facing the circuit board 3. Then, the sealing resin 7 permeates into the bottom of the functional element 5 according to the air stream in the direction of the arrows shown in FIG. 8B. By keeping in this stage for a while, as shown in FIG. 8C, it is possible to fill a gap 9 between the functional element 5 and the circuit board 3, the aperture section 6, and the surroundings of the bumps 4, with the sealing resin 7.

For the viscosity of the sealing resin 7 to be used, the viscosity is greater than or equal to 0.5 Pa·s and less than or equal to 3.0 Pa·s at room temperature, for example.

Next, as shown in FIG. 9, by canceling the suction of the stage 21, and removing the circuit board 3 on which the functional element 5 is mounted from the stage 21, the module 10 of the present invention is obtained.

According to the first manufacturing method of the module of the present invention, since the aperture section 6 is formed in the circuit board 3 (insulating layer 1), the area of overlap between the functional element 5 and the circuit board 3 is small, and hence it is possible to reduce the probability of contamination by bubbles. Even if bubbles contaminate the sealing resin 7, the bubbles can be eliminated via the aperture section 6. As a result, it is possible to improve the yield, and obtain a module 10 in which it is difficult for bubbles to exist in the sealing resin 7. Furthermore, since sealing by the sealing resin can be performed while confirming, from the aperture section 6, whether or not there are bubbles, it is possible to improve the work efficiency.

Moreover, by injecting the sealing resin 7 from both sides of the functional element 5, there is concern about bubbles being included when the sealing resin 7 meets under the functional element 5. However, according to the manufacturing method of a module of the present invention, it is possible to eliminate the bubbles via the aperture section 6.

Furthermore, by filling the sealing resin 7 under suction, it is possible to make the second face 1b side of the insulating layer 1 be at a lower pressure than the first face 1a side of the insulating layer 1, so that it is possible to enhance the flow of the sealing resin 7 from both sides 5a and 5b of the functional element 5 to the aperture section 6, and to fill the gap 9 between the functional element 5 and the circuit board 3, and the aperture section 6, with the sealing resin 7. As a result, it is possible to shorten the time required for filling the sealing resin 7. In particular, suctioning enables the sealing resin 7 to flow efficiently over a wide area. Therefore, in the case where the functional element 5 is large, by using the manufacturing method of the present invention, it is possible to manufacture a module easily in which it is difficult for bubbles to contaminate the sealing resin 7. Moreover, if suctioning and degassing are performed under vacuum, it is possible to eliminate bubbles more effectively.

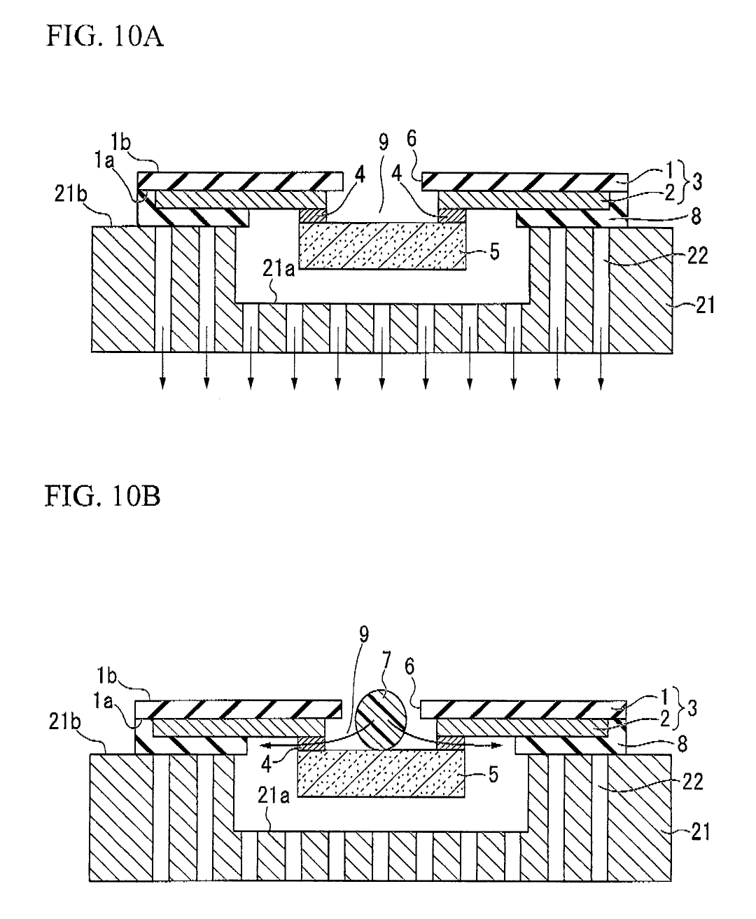

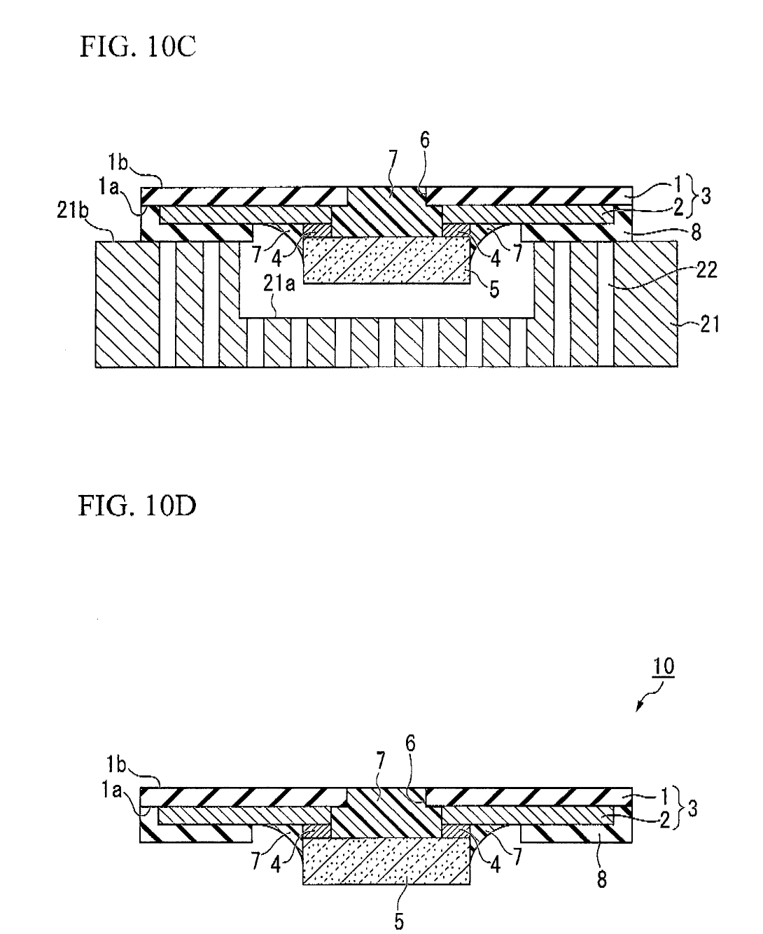

FIGS. 10A to 10D are cross-sectional process diagrams schematically showing another example of a manufacturing method (second manufacturing method) of a module of the present invention.

The process of mounting the functional element 5 on the circuit board 3 is the same as in the first manufacturing method, and is the same as the processes described in FIGS. 6A, 6B and 6C, and FIGS. 7A and 7B. Therefore, it is omitted.

Firstly, as shown in FIG. 10A, the circuit board 3 on which the functional element 5 is mounted is inverted compared with the first manufacturing method, and it is placed on the stage 21 in which a plurality of suction holes 22 is provided such that the functional element 5 is on the stage 21 side. The stage 21 has a recess 21a in which at least the region facing the functional element 5 is concave. The recess 21a can accommodate the functional element 5, so the adhesion between the circuit board 3 and the stage 21 can be improved.

Afterwards, by suctioning atmospheric gas from the suction holes 22 in the direction indicated by the arrows in FIG. 10A, the circuit board 3 on which the functional element 5 is mounted is fixed on the stage 21. By suctioning in this manner, the first face 1a side of the insulating layer 1 and the recess 21a of the stage 21 are at a lower pressure than the second face 1b side of the insulating layer 1 and the aperture section 6, so the atmospheric gas flows from the aperture section 6 of the circuit board 3 toward the recess 21a side of the stage 21.

Next, as shown in FIG. 10B, the sealing resin 7 is applied to the aperture section 6 of the circuit board 3.

Then, the sealing resin 7 permeates between the functional element 5 and the conductors 2 according to the air stream in the direction indicated by the arrows in the figure. By keeping in this stage for a while, as shown in FIG. 10C, it is possible to fill the gap between the functional element 5 and the circuit board 3, the aperture section 6, and the surroundings of the bumps 4, with the sealing resin 7:

For the viscosity of the sealing resin 7 to be used, the viscosity is greater than or equal to 0.5 Pa·s and less than or equal to 7.0 Pa·s at room temperature, for example.

Next, as shown in FIG. 100, by canceling the suction of the stage 21, and removing the circuit board 3 on which the functional element 5 is mounted from the stage 21, the module 10 of the present invention is obtained.

According to the second manufacturing method of a module of the present invention, since the sealing resin 7 can be disposed in the aperture section 6, it is easy to locate the sealing resin 7 at an appropriate position when it is disposed compared with the first manufacturing method in which the sealing resin 7 is disposed from the side of the functional element 5. Furthermore, since the sealing resin 7 is disposed above the functional element 5 in the vertical direction for filling, bubbles move upward. Therefore, bubbles move to a region away from the electrical contacts of the bumps 4 and the conductors 2 so that they can be eliminated via the aperture section 6 easily. As a result, it is possible to improve the yield, and obtain a module 10 in which it is difficult for bubbles to exist in the sealing resin 7. Furthermore, since sealing by the sealing resin 7 can be performed while confirming, from the aperture section 6, whether or not there are bubbles, it is possible to improve the work efficiency.

Moreover, by filling the sealing resin 7 in a state under suction, it is possible to make the first face 1a side of the insulating layer 1 be at a lower pressure than the second face 1a side of the insulating layer 1. As a result, it is possible to enhance the flow of the sealing resin 7 from the aperture section 6 to both sides 5a and 5b of the functional element 5, and to fill the gap 9 between the functional element 5 and the circuit board 3, and the aperture section 6, with the sealing resin 7. Therefore, it is possible to shorten the time required for filling the sealing resin 7.

In particular, in the second manufacturing method of the present embodiment, it is possible to reduce the time needed to apply the sealing resin 7 compared with the first manufacturing method. In the first manufacturing method, after the sealing resin 7 permeates between the functional element 5 and the conductors 2, it extends to the functional element 5, and the gap to the aperture section 6 is filled up. Therefore, it takes time for the amount of sealing resin required to move and fill up to the aperture section 6. In contrast with this, in the second manufacturing method, the sealing resin 7 permeates between the functional element 5 and the conductors 2 after it extends to the functional element 5. As a result, it is possible to shorten the filling time of the sealing resin 7 compared with the first manufacturing method.

Moreover, suctioning enables the sealing resin 7 to flow efficiently over a wide area. Accordingly, even in the case where the functional element 5 is large, by using the manufacturing method of the present invention, it is possible to manufacture a module easily in which it is difficult for bubbles to contaminate the sealing resin 7. Furthermore, if suctioning and degassing are performed under vacuum, it is possible to eliminate bubbles more effectively.

In the first manufacturing method and the second manufacturing method, in the resin sealing process, it is preferable to inject the sealing resin 7 such that a region 7a is formed that protrudes toward the second face 1b of the insulating layer 1 from the aperture section 6, and extends to an area wider than the aperture section 6 on the second face 1b of the insulating layer 1. The region 7a can be formed easily by adjusting the time for filling the sealing resin 7, the strength of suctioning atmospheric gas, and the like. By forming the region 7a, it is possible to manufacture a module 10B of the second embodiment in which the resistance against external impact can be improved.

For methods of sealing the gap between the functional element 5 and the circuit board 3, and the aperture section 6, with the sealing resin 7, a variety of methods other than the above-described one can be used. For example, the sealing may be performed not only by a method of filling using capillary action or the like, and a method of direct filling of the sealing resin 7, but also by a casting process, a coating process, a dipping method, a potting method, a immersion coating method, or the like, for example. By providing the aperture section 6, bubbles can be eliminated more effectively.

### EXAMPLES

### Example 1

A module of the present invention as shown in FIG. 3 was manufactured.

Firstly, a printed circuit board was made in which polyimide with a thickness of 40 μm was formed as an insulating layer, and conductors with a thickness of 18 μm were patterned to produce a circuit. Next, an aperture section of 14.5 mm×14.5 mm was formed at the location in the insulating layer where a functional element was to be mounted. Afterwards, a semiconductor element with dimensions of 15 mm×15 mm on which gold bumps with a height of 15 μm were formed as electrodes, was mounted on the circuit board in which the aperture section was formed. Next, by placing the circuit board on which the semiconductor element was mounted on a stage in which a plurality of suction holes was provided, as shown in FIG. 8A, and by attracting it via the suction holes in the direction indicated by the arrows in FIG. 8A, the circuit board was fixed on the stage. Next, as shown in FIG. 8B, sealing resin with a viscosity of 1.5 Pa·s at room temperature was applied to the circuit board and the two sides of the semiconductor element facing the circuit board. Then, the sealing resin permeated under the functional element following the air flow in the direction of the arrows shown in FIG. 8B, and by keeping in this state for a while, as shown in FIG. 8C, the sealing resin filled the gap between the functional element and the circuit board, the aperture section, and the surroundings of the gold bumps, and the module of the example as shown in FIG. 3 was obtained.

A quantity of five samples of the module of the above-described example was manufactured, and contamination by bubbles in each of the sealing resins was determined visually. As a result, the five samples showed no contamination by bubbles in the sealing resin,

### Comparative Example 1

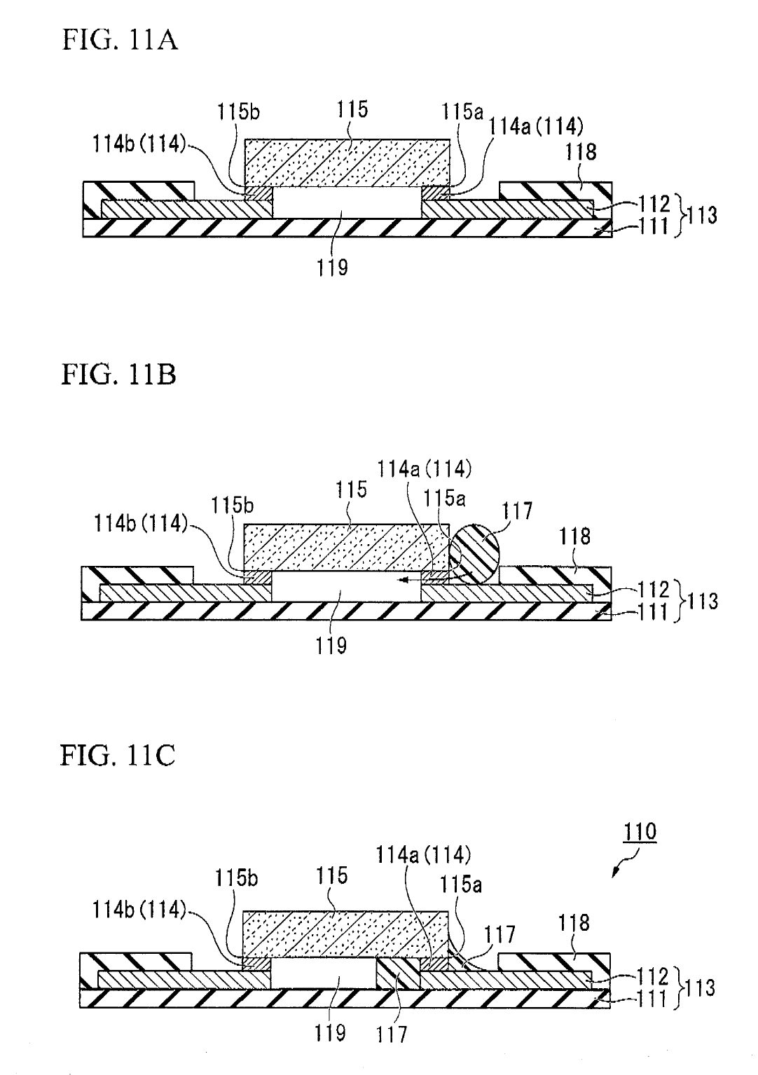

A module 110 of a comparative example 1 was manufactured using a method as shown in FIGS. 11A to 11C.

Firstly, as shown in FIG. 11A, a printed circuit board 113 was made in which polyimide with a thickness of 40 μm was formed as an insulating layer 111, and conductors 112 with a thickness of 18 μm were patterned to produce a circuit. Next, a semiconductor element 115 with dimensions of 15 mm×15 mm on which gold bumps 114 with a height of 15 μm were formed as electrodes, was mounted on the printed circuit board 113. Subsequently, as shown in FIG. 11B, sealing resin with a viscosity of 1.5 Pa·s was applied to one side 115a of the semiconductor element 115.

Then, as shown in FIG. 11C, by capillary action between the conductors 112 of the printed circuit board 113, the surroundings of the closest bump 114a was successfully sealed with the sealing resin 117. However, the sealing resin 117 did not reach the opposite side 115b.

### Comparative Example 2

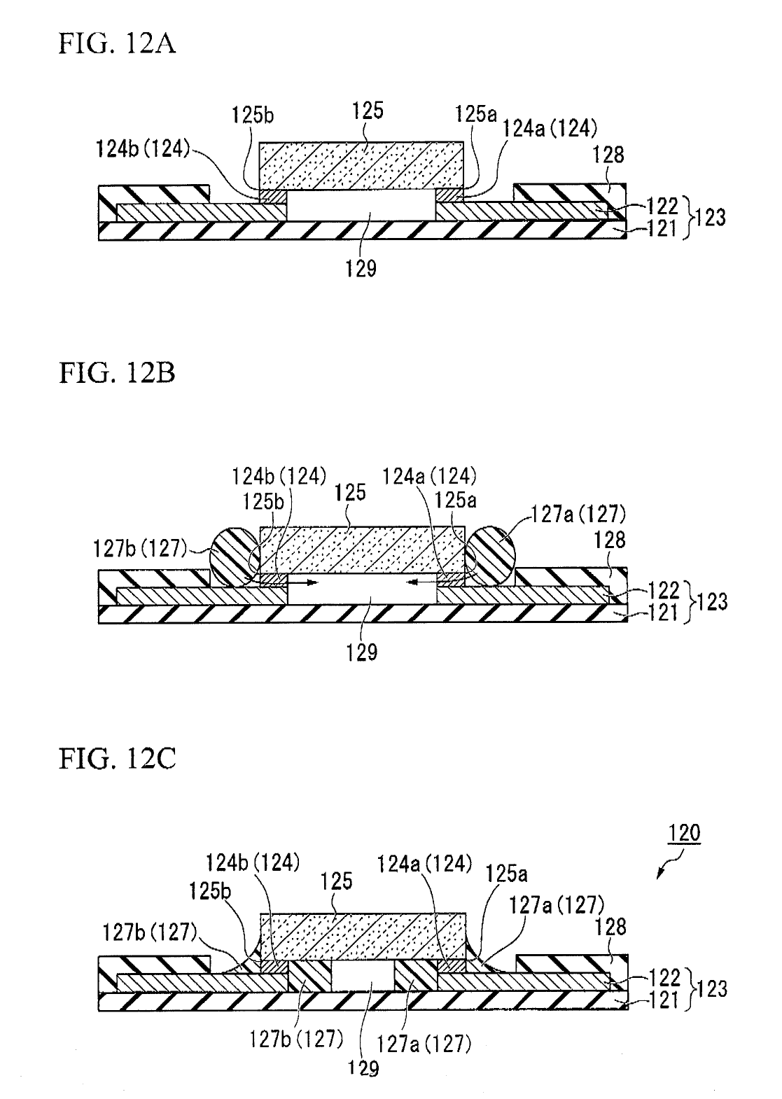

A module 120 of a comparative example 2 was manufactured using a method as shown in FIGS. 12A to 12C.

Firstly, as shown in FIG. 12A, similarly to comparative example 1, a semiconductor element 125 was mounted on a printed circuit board 123. Next, as shown in FIG. 12B, sealing resin with a viscosity of 1.5 Pa·s was applied to the two facing sides 125a and 125b of the semiconductor element 125.

Then, as shown in FIG. 12C, by capillary action between the conductors 122, the surroundings of the bumps 124 closest to the two sides were successfully sealed with the sealing resin 127. However, a gap 129 between the semiconductor element 125 and the printed circuit board 123 was not completely sealed with the sealing resin 127, which created a shape whereby air was enclosed in the sealing resin 127, resulting in bubbles contaminating the lower part of the semiconductor element 125.

From those results, it was confirmed that according to the present invention, even if a functional element has the large size of 15 mm×15 mm, the gap between the functional element and the circuit board, the aperture section, and the surroundings of bumps, can be sealed without bubbles contaminating the sealing resin.

### INDUSTRIAL APPLICABILITY

According to the present invention, even in the case where a large functional element is mounted, a module can be obtained in which the probability of contamination by bubbles is reduced.

1. A module provided with; a circuit board in which conductors are patterned on a first face of an insulating layer, and a functional element that is mounted on the conductors face down via bumps, wherein the module includes:
an aperture section, which is formed in a thickness direction of the insulating layer in an area at a location of the circuit board where the functional element is mounted, which is smaller than a projected surface of the functional element and is inside of a region where the bumps are joined with the conductors; and
a sealing resin that seals a gap between the functional element and the circuit board, and the aperture section.

2. The module according to claim 1, wherein
the sealing resin protrudes from the aperture section to a second face of the insulating layer, and has a region that spreads to an area wider than the aperture section.

3. A circuit board in which conductors are patterned on a first face of an insulating layer, and a functional element is mounted face down on the conductors,
wherein an aperture section is formed in a thickness direction of the insulating layer in an area that is smaller than a projected surface of the functional element and is inside of a region where the functional element is electrically joined with the conductors.

4. A method of manufacturing a module provided with; a circuit board in which conductors are patterned on a first face of an insulating layer, and a functional element that is mounted on the conductors face down via bumps, and in which an aperture section is formed in a thickness direction of the insulating layer, in an area at a location of the circuit board where the functional element is mounted that is smaller than a projected surface of the functional element and is inside of a region where the bumps are joined with the conductors, and a gap between the functional element and the circuit board, and the aperture section, are sealed using a sealing resin, the method including:
mounting the functional element on the conductors of the circuit board via the bumps; and
sealing the gap between the functional element and the circuit board, and the aperture section, using the sealing resin.

5. The method of manufacturing a module according to claim 4, wherein
in the resin sealing, the sealing resin is injected such that it protrudes from the aperture section to a second face of the insulating layer, and forms a region that spreads to an area wider than the aperture section on the second face of the insulating layer.

6. The method of manufacturing a module according to claim 4, wherein
in the resin sealing, the sealing resin is injected from at least one pair of opposing sides of the functional element.

7. The method of manufacturing a module according to claim 4, wherein
in the resin sealing, the sealing resin is injected from the aperture section.

8. The method of manufacturing a module according to claim 6, wherein
in the resin sealing, the sealing resin is injected with a second face side of the insulating layer being at a lower pressure than the first face side of the insulating layer.

9. The method of manufacturing a module according to claim 7, wherein
in the resin sealing, the sealing resin is injected with the first face side of the insulating layer being at a lower pressure than a second face side of the insulating layer.

10. The method of manufacturing a module according to claim 8, wherein
the resin sealing comprises:
mounting the circuit board on a suction stage on which a plurality of suction holes is provided such that the second face of the circuit board is on the suction stage side;
fixing the circuit board on the suction stage by suctioning from the suction holes; and
applying the sealing resin to at least one pair of opposing sides of, the functional element in a state in which it is sucked down, and filling the gap between the functional element and the circuit board, and the aperture section, with the sealing resin.

11. The method of manufacturing a module according to claim 10, wherein
a recess is provided in a location of the suction stage, facing the aperture section.

12. The method of manufacturing a module according to claim 9, wherein
the resin sealing comprises:
mounting the circuit board on a suction stage on which a plurality of suction holes is provided such that the functional element is on the suction stage side;
fixing the circuit board on the suction stage by suctioning from the suction holes; and
applying the sealing resin from the aperture section in a state in which it is sucked down, and filling the gap between the functional element and the circuit board, and the aperture section, with the sealing resin.

13. The method of manufacturing a module according to claim 12, wherein
a recess is provided in a location of the suction stage, facing the functional element.
